(19) United States
(12) Patent Application Publication
(10) Pub. No.: US 2010/0000470 A1
(43) Pub. Date: Jan. 7, 2010

(54) WAFER-POSITIONING MECHANISM

(75) Inventor: Masanori Sakata, Sagamihara-shi (JP)

Correspondence Address: KNOBBE MARTENS OLSON & BEAR LLP, 2040 MAIN STREET, FOURTEENTH FLOOR, IRVINE, CA, 92614, US

(73) Assignee: ASM JAPAN K.K., Tokyo (JP)

(21) Appl. No.: 12/166,553

(22) Filed: Jul. 2, 2008

(51) Int. Cl. C23C 16/00

(52) U.S. Cl. 118/728

(57) ABSTRACT

A wafer-positioning mechanism includes a susceptor having an upper surface for supporting a wafer thereon, which is slanted with respect to a horizontal plane at an angle such that the wafer on the upper surface slides with an aid and does not slide without the aid. The aid is a gas flowing out of the upper surface against the reverse side of the wafer facing the upper surface. The upper surface has a protrusion for stopping the wafer from sliding beyond the protrusion in the sliding direction by contacting an edge of the wafer where the wafer is positioned on the upper surface for wafer processing.

### BACKGROUND OF THE INVENTION

1. Field of the Invention

The invention pertaining to the present application for patent relates to a high-precision positioning mechanism applied to a transfer system that requires high-precision positioning, particularly in the process of transferring a wafer to the process chamber and setting the wafer on the susceptor.

2. Description of the Related Art

In semiconductor device manufacturing, many processes require that a wafer be positioned accurately at the specified position on the supporting body designed to retain a wafer (hereinafter referred to “susceptor”) in order to process the wafer. For example, plasma CVD and etching apparatuses, among others, will cause the wafer to deviate from the specified position on the susceptor if the wafer is not positioned correctly, which can lead to various problems such as variable film thickness, attachment of foreign particles, plasma damage, and non-uniform edge exclusion (position of edge-shielding film).

General methods used to address the aforementioned problems include providing a counterbore in the susceptor or setting a guide pin to limit the wafer installation position, thereby allowing the wafer to be placed accurately at the specified position. Various other ingenious ideas are also used, in addition to the above, such as increasing the precision of the transfer robot and implementing positioning by means of image processing technology.

However, the conventional methods mentioned above are all intended to accurately place the wafer at the specified position on the susceptor and therefore present various problems, where the reported problems include high facility cost, inability to increase speed, and poor position accuracy.

### SUMMARY OF THE INVENTION

The present invention can accomplish one or more of the above-mentioned objects in various embodiments. However, the present invention is not limited to the above objects, and in embodiments, the present invention may exhibit effects other than the objects.

In an embodiment of the present invention, a wafer is positively slid upon an upper surface of a susceptor until the wafer is properly positioned on the upper surface for wafer processing. In the embodiment, the positioning of the wafer can easily, inexpensively, quickly, and/or accurately be accomplished. In an embodiment, the step of positively sliding the wafer can be accomplished using a slanted upper surface of the susceptor with respect to a horizontal plane and a gas discharge system for discharging gas against the reverse side of the wafer placed on the upper surface of the susceptor.

For purposes of summarizing aspects of the invention and the advantages achieved over the related art, certain objects and advantages of the invention are described in this disclosure. Of course, it is to be understood that not necessarily all such objects or advantages may be achieved in accordance with any particular embodiment of the invention. Thus, for example, those skilled in the art will recognize that the invention may be embodied or carried out in a manner that achieves or optimizes one advantage or group of advantages as taught herein without necessarily achieving other objects or advantages as may be taught or suggested herein.

Further aspects, features and advantages of this invention will become apparent from the detailed description of the preferred embodiments which follow.

### BRIEF DESCRIPTION OF THE DRAWINGS

These and other features of this invention will now be described with reference to the drawings of preferred embodiments which are intended to illustrate and not to limit the invention. The drawings are oversimplified for illustrative purposes and are not to scale.

FIG. 1 is a schematic cross sectional view of a plasma CVD apparatus according to an embodiment of the present invention.

FIG. 2 is a schematic plan view of a plasma CVD apparatus according to an embodiment of the present invention.

FIG. 3 is a schematic cross sectional view of a plasma CVD apparatus according to another embodiment of the present invention.

FIG. 4 is a schematic cross sectional view of a susceptor angle adjusting mechanism according to an embodiment of the present invention.

FIG. 5 is a schematic perspective view of an susceptor angle adjusting mechanism according to an embodiment of the present invention.

### DETAILED DESCRIPTION OF THE PREFERRED EMBODIMENTS

The present invention will be explained in detail with reference to preferred embodiments which are shown for illustrative purposes, rather than limiting the present invention.

In an aspect, the disclosed embodiments provide a wafer-positioning mechanism comprising: a susceptor having an upper surface for supporting a wafer thereon, said upper surface being slanted with respect to a horizontal plane at an angle such that the wafer on the upper surface slides with an aid (but does not slide without the aid in another embodiment), said aid being a gas flowing out of the upper surface against the reverse side of the wafer facing the upper surface, said upper surface having a protrusion for stopping the wafer from sliding beyond the protrusion in the sliding direction by contacting an edge of the wafer where the wafer is positioned on the upper surface for wafer processing.

In the above, in an embodiment, the angle may be 1° to 15° (including 5° to 10°) with respect to the horizontal plane. In an embodiment, in the absence of the sliding aid (e.g., absence of gas flow reducing friction), the wafer rests on the angled susceptor by operation of gravity alone, without movement. In another embodiment, the wafer is capable of movement on the angled support surface under the influence of gravity alone, even in the absence a sliding aid (e.g., in the absence of gas flow reducing friction), and the movement is restricted only by the protrusion.

In any of the foregoing embodiments, the protrusion may be comprised of multiple guide pins disposed only in a lower half of the slanted upper surface or the protrusion may be comprised of a step or steps disposed only in a lower half of the slanted upper surface. In any of the foregoing embodiments, the protrusion may be integrally formed with the upper surface and made of the same material as that constitutes the upper surface.

In any of the foregoing embodiment, the upper surface of the susceptor may have multiple holes for discharging gas therefrom against the reverse side of the wafer placed on the upper surface. In the above, the multiple holes may be holes for wafer lift pins.

In any of the foregoing embodiments, the susceptor may be supported by a susceptor support, wherein an axis of the susceptor support is vertical. Alternatively, the susceptor may be supported by a susceptor support, wherein an axis of the susceptor support is perpendicular to the upper surface of the susceptor.

In any of the foregoing embodiment, the wafer-positioning mechanism may further comprise a shower plate disposed facing and parallel to the susceptor.

In another aspect, the disclosed embodiments provide a method for positioning a wafer on an upper surface of a susceptor, comprising: (i) placing a wafer on lift pins extending from an upper surface of a susceptor; (ii) retracting the lift pins to place the wafer on the upper surface; and (iii) positively sliding the wafer upon the upper surface until the wafer is positioned for wafer processing.

In the above, in an embodiment, the upper surface may be slanted with respect to a horizontal plane at an angle such that the wafer on the upper surface slides with an aid (but does not slide without the aid in another embodiment), said aid being a gas flowing out of the upper surface against the reverse side of the wafer facing the upper surface, said upper surface having a protrusion for stopping the wafer from sliding beyond the protrusion in the sliding direction by contacting an edge of the wafer where the wafer is positioned on the upper surface for wafer processing, wherein the step of positively sliding the wafer may comprises: (I) discharging gas from the upper surface of the susceptor against the reverse side of the wafer, thereby sliding the wafer toward the protrusion; and (II) stopping the wafer at the protrusion by contacting an edge of the wafer.

In any of the foregoing embodiments, the angle may be 1° to 15° (including 5° to 10°) with respect to the horizontal plane.

In any of the foregoing embodiments, the gas may be discharged from multiple holes formed on the upper surface where the wafer is placed. In an embodiment, the multiple holes may be holes for wafer lift pins.

In still another aspect, the disclosed embodiments provide an apparatus for processing a wafer, comprising: (a) a reaction chamber; (b) the susceptor of any of the above aspects disposed in the reaction chamber; and (c) a shower plate disposed in the reaction chamber, said shower plate being disposed facing and parallel to the susceptor.

In the above, in an embodiment, the apparatus may further comprise a radio-frequency (RF) power source for applying RF power between the shower plate and the susceptor to generate a plasma therebetween.

In any of the foregoing embodiments, the angle of the susceptor may be 5° to 15° with respect to the horizontal plane.

In any of the foregoing embodiments, the susceptor may be supported by a susceptor support, wherein an axis of the susceptor support is vertical. Alternatively, the susceptor may be supported by a susceptor support, wherein an axis of the susceptor support is perpendicular to the upper surface of the susceptor.

In any of the foregoing embodiments, the angle of the susceptor may be adjustable by mechanically adjusting an angle of upper surface of the susceptor relative to the axis of the susceptor support.

Preferred embodiments of the present invention are described with reference to drawings attached, but the invention should not be limited thereto.

The preferred embodiments will be further explained in more detail.

(Configuration of Apparatus)

[Overall]

In an embodiment, the present invention provides a susceptor for parallel-plate, capacitive-coupling plasma CVD apparatuses, wherein such susceptor has: (a) a device to cause a wafer to slide in a reliable manner when the wafer is placed on the susceptor; (b) a device to stop the wafer at the specified position; and (c) a inclination needed to cause the wafer to slide in the same direction. Although the present invention can be applied favorably to parallel-plate, capacitive-coupling plasma CVD apparatuses, it can also be applied to other apparatuses such as ALD (atomic layer deposition) apparatuses.

[Susceptor]

In an embodiment, the present invention provides a susceptor having functions equivalent to those provided by a conventional susceptor, as well as a function to cause the wafer to slide, a function to receive the wafer (such as a guide pin), and an inclination in the receiving direction of the wafer.

[Wafer-Sliding Function]

The problem of the wafer sliding on the susceptor has occurred during transfer under various conditions. Investigations into the conditions in which a wafer slides reveal that the sliding of a wafer depends significantly upon the condition of the back side of the wafer and also on the preceding process. The condition of the back side of the wafer includes the condition of gas generating from the back side of the wafer when the wafer is carried into the chamber, because this gas acts as a lubricant to promote the sliding. For example, the wafer tends to slide more in the following order:
SiO2 film formed by TEOS gas by means of plasma CVD
SiC or SiO2 film formed by means of plasma CVD
SiO2 film formed by means of thermal CVD
SiN formed by means of plasma/thermal CVD
Bare silicon used in plasma/thermal CVD (Virtually the wafer does not slide at all.)

As for the preceding process, the wafer slides more in the wafer cleaning process before the wafer film forming process, compared to other preceding process.

The cleaning before film is formed on the wafer is normally implemented as wet cleaning, where water used for cleaning remains at the back side of the wafer and gasifies when the wafer is placed in position. Based on the above, gas generating from the back side of the wafer is considered a cause of wafer sliding, and the present apparatus is designed to actively utilize this mechanism. In an embodiment of the present invention, the target wafer can be always placed at the planned position regardless of the type of the film formed on the wafer or regardless of the type of the preceding process, by simply promoting the sliding of the wafer. In other words, the present function comprises an inclination of the susceptor and a device to supply gas to the back side of the wafer from the susceptor. With the present function, once a wafer is placed on the susceptor the wafer will slide in the inclining direction and contact the guide located at the bottom edge in the inclining direction, upon which the wafer will stop and assume its position accurately.

As for the amount of gas to be supplied, at least the same amount as the gas generating from the back side of the wafer or more (including an amount twice or more or three times or more) is deemed necessary. If the flow rate is too high, however, the wafer may move about or otherwise become unstable on the susceptor surface. Accordingly, the flow rate is adjusted to, for example, a range of 0.01 sccm or more but less than 1 sccm (including 0.05 sccm, 0.1 sccm, 0.5 sccm and any values between the foregoing numbers; or between a range of approx. 0.1 sccm and 0.5 sccm in an embodiment). The type of gas is not limited in any way, as long as the gas does not contribute to reaction. Among others, an inert gas can be used favorably, where representative examples include Ar and He.

With regard to the timing at which to start supply of gas, supply of gas can be started immediately before a wafer is placed, simultaneously as a wafer is placed, or after a wafer has been placed, for example. However, a preferred timing is immediately before a wafer is placed. On the other hand, supply of gas can be stopped either when the wafer reaches the specified position or immediately before that, but a preferred timing is when the wafer reaches the specified position. The same timings may apply when vibration is used, but controlling the sliding of the wafer using gas is more preferable than causing the wafer to slide by means of vibration, because vibration may generate particles and dust.

The gas flow rate may increase temporarily when supply of gas is started, and therefore gas is supplied at a stable flow rate from the very beginning so that the wafer will not move about due to the aforementioned temporary increase in the flow rate. Alternatively, the gas flow rate may be intentionally increased temporarily when supply of gas is started, in order to promote the movement of the wafer and then gradually decrease the gas flow rate thereafter.

If lift pin holes are to be used as gas supply ports, in an embodiment the inner diameter of the lift pin hole is adjusted to a range of approx. 2 mm to 10 mm (such as 4 mm). The outer diameter of the pin is adjusted to a range of 60% to 95% of the pin hole, such as approx. 90%. Normally three lift pin holes are used, but the number of lift pin holes is not limited to the aforementioned number for the purposes of gas supply and any number of lift pin holes may be provided as long as there is at least one hole; however, preferably gas is supplied from multiple holes. Also, a dedicated gas supply hole may be provided in addition to the lift pin holes. For a dedicated gas supply hole, the gas channel may be inclined so that gas will be injected in the sliding direction of the wafer.

The present function can also be achieved with ease by utilizing the pin holes for moving the wafer up and down, which are provided by almost all susceptors of conventional types.

Other methods to cause the wafer to slide include using a susceptor having numerous holes throughout its body to supply gas from over the entire susceptor, causing the susceptor to vibrate and thereby move the wafer, and combining the aforementioned two methods.

[Wafer-Receiving Function]

Almost all susceptors of conventional types have some sort of guide function to prevent the wafer from sliding. The present function can also be achieved by using this guide function of a conventional susceptor. However, use of conventional guides requires considerable attention to ensure proper positioning because the guides are provided in 360° directions, which means that these guides will also affect the process over a range of 360°. On the other hand, the proposed function uses an inclined susceptor to cause the wafer to slide in the inclining direction.

This arrangement makes it sufficient to provide a receiving member only in the inclining direction. For example, providing two guide pins, etc., in this direction is enough. In other words, multiple guide pins need to be provided only in the moving direction of the wafer, and no guide pins are necessary on the opposite side. As a result, the wafer-receiving guides can be optimized and minimized, which provides the advantage of minimizing the impact on the process.

The number of guide pins need not be two, and three, four or more guide pins may be provided. However, two pins are enough to accurately stop the wafer at the specified position. Although the positions of pins are not limited in any way, the pins should be set at low positions along the inclined surface where they will not interfere with the carrying-in of the wafer from the gate valve. If edge-shielding rings, etc., are to be used, the pins should be set at appropriate positions and heights so as not to interfere with such rings. In an embodiment, a height gap may be used instead of pins (providing at least one projection having a sufficient width is enough to replace the pins). This height gap is provided not along the entire circumference of the wafer, but only along the outer periphery covering a dimension smaller than a semi-circle in the carry-in direction of the wafer. In an embodiment the height of the pin or height gap may be roughly the same as the wafer thickness (within ±20% of the wafer thickness), while in another embodiment the height is adjusted to approx. 1 mm from the susceptor surface.

Also, the pins may be provided as part of the susceptor, or specifically as projections on the susceptor surface. In addition, the pins may be structured in such a way that they project only when the wafer is positioned, and remain stored in the susceptor at other times. The pins may be made of, for example, alumina or other ceramics, or alumite or other anodized material.

[Inclination of Susceptor]

The present function can be implemented in various apparatuses, some examples of which are listed below:
Apparatus having a mechanism to adjust the inclination of the susceptor itself synchronously with the upper electrode
Apparatus having an upper electrode and a susceptor, both of which have a specific inclination from the beginning
An apparatus whose entire structure is inclined

A desired degree of inclination can be selected as deemed necessary, but an appropriate inclination is selected by considering the stability of plasma (with a parallel-plate, capacitive-coupling apparatus, generation of plasma may be affected as the inclination increases), transfer stability of the wafer (a large inclination may cause position deviation during transfer by the robot arm or cause the wafer to become unstable and slide when it is placed in position), and wafer stability on the wafer lift pins (a large inclination may cause the wafer to slide at the tip of the pins when the wafer is moved up and down using the pins, thereby resulting in position deviation), among others.

In view of the above, in an embodiment, the inclination angle is set within a range of up to approx. 15° (including 1°, 3°, 5°, 7°, 10°, 12° and any values between the foregoing numbers; preferably in a range of 3° to 10°, or more preferably in a range of 5° to 7°) so as not to affect the process.

The direction of inclination is not limited in any way, but in an embodiment the susceptor inclines in such a way that its height becomes lower in the direction in which the wafer is carried into the reactor through the gate valve, in order to ensure a sufficient distance (such as a distance between 1 mm and 10 mm) over which the wafer can move on the susceptor from the position where it is placed on the wafer pins until the guide pin position. In an embodiment, however, the inclination may be provided in the direction of a 90° or greater angle relative to the carry-in direction.

The present invention is explained below using examples. It should be noted, however, that the present invention is not at all limited to these examples.

### EXAMPLE 1

### Only the Susceptor and Upper Electrode are Inclined

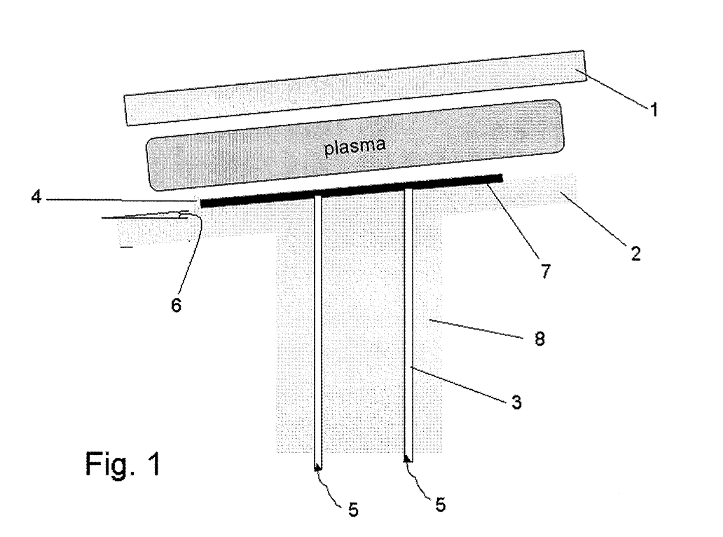

FIG. 1 is a schematic view showing an example where only the susceptor and upper electrode are inclined. The reaction chamber and all other members are not illustrated. A susceptor 2 functions as the lower electrode, while a shower plate 1 functions as the upper electrode, and the susceptor 2 and shower plate 1 constitute the parallel-plate electrodes between which plasma is generated. In this example, an inclination angle 6 of the top face of the susceptor is approx. 10° relative to the horizontal plane. A support 8 of the susceptor 2 is set vertically to the horizontal plane, and the susceptor is inclined by the aforementioned inclination angle. A wafer 7 is placed onto lift pins 3 at a position raised from the surface of the susceptor 2, and then placed on the surface of the susceptor 2 as the lift pins 3 are lowered. At this time, a gas 5 is introduced into holes in which the lift pins 3 are stored, in order to cause the gas to contact the back side of the wafer 7 and thereby cause the wafer 7 to slide over the surface of the susceptor 7 inclined by the aforementioned inclination angle 6, until it contacts guide pins 4.

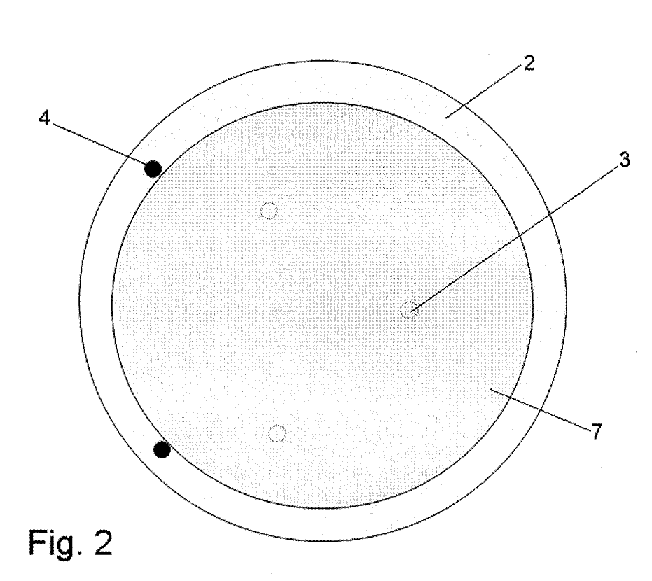

As shown in the top view in FIG. 2, two guide pins 3 are provided in this example in such a way that the pins contact the wafer 7 at the 45° positions (normally between 30° and 60°) to the right and left of the wafer center relative to the sliding direction of the wafer. Although concealed by the wafer 7, three lift pins 3 are provided and they are indicated by dotted lines in the figure.

### EXAMPLE 2

### The Entire Apparatus is Inclined

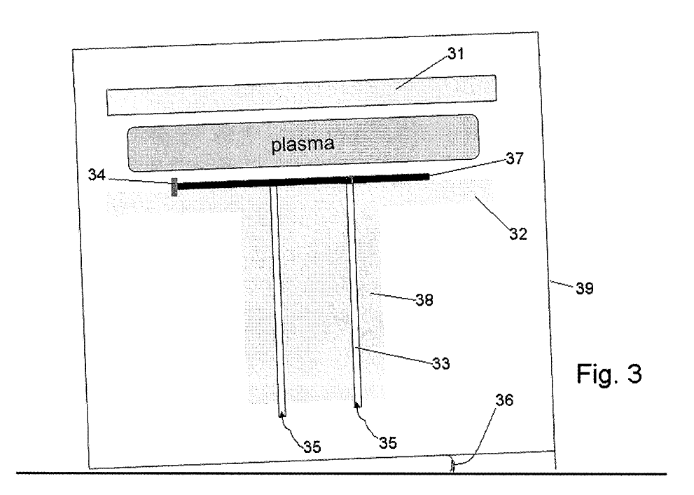

FIG. 3 is a schematic view showing an example where the entire apparatus is inclined in addition to the susceptor and upper electrode. A reaction chamber 39 is indicated schematically by a square border. A susceptor 32 functions as the lower electrode, while a shower plate 31 functions as the upper electrode, and the susceptor 32 and shower plate 31 constitute the parallel-plate electrodes between which plasma is generated. In this example, the entire apparatus (reaction chamber) is inclined by an inclination angle 36 (approx. 10°) relative to the horizontal plane. The axis of a support 38 of the susceptor 32 is orthogonal to the surface of the susceptor 32 and nothing inside the reaction chamber is inclined except that the entire reaction chamber is inclined. A wafer 37 is placed onto lift pins 33 at a position raised from the surface of the susceptor 32, and then placed on the surface of the susceptor 32 as the lift pins 33 are lowered. At this time, a gas 35 is introduced into holes in which the lift pins 33 are stored, in order to cause the gas to contact the back side of the wafer 37 and thereby cause the wafer 37 to slide over the surface of the susceptor 37 inclined by the aforementioned inclination angle 36, until it contacts guide pins 34.

The guide pins 33 are set at the positions shown in the top view in FIG. 2.

### EXAMPLE 3

### The Susceptor Angle is Made Variable

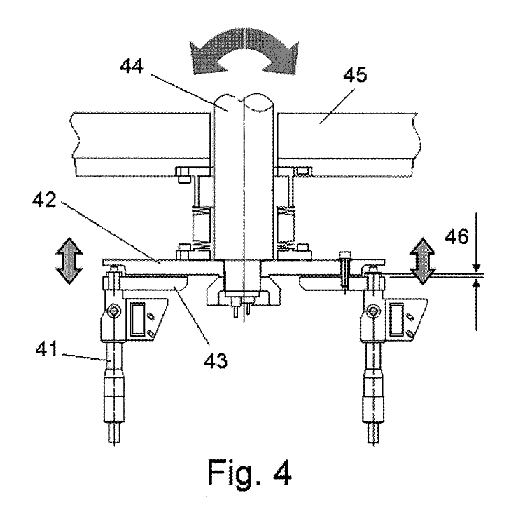

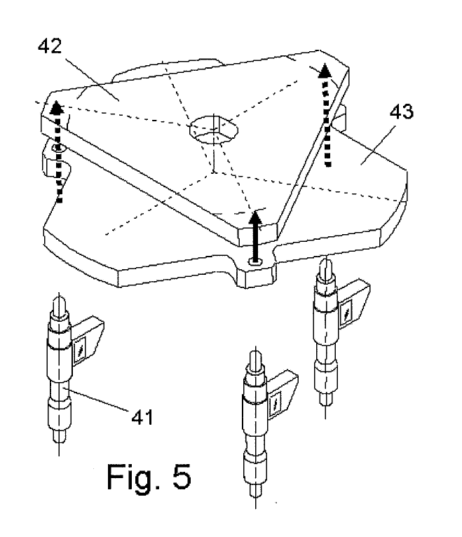

FIG. 4 (schematic cross sectional view) and FIG. 5 (schematic perspective view) show an example of a mechanism whereby the susceptor angle is made variable. The susceptor is supported along a line drawn by extending an axis 44 upward, and the axis 44 can be inclined by a desired angle relative to a bottom 45 of the wafer transfer chamber provided below the wafer reaction chamber. A desired inclination angle can be achieved by using up/down devices 41 (such as micro-heads) to move up and down a support plate 42 on which the axis 44 is supported, and thereby adjusting a gap 46 between the support plate 42 and a base plate 43. There must be at least three up/down devices 41 in order to adjust the angle in any given direction in a stable manner. However, providing at least one up/down device is sufficient if the angle is adjusted only in one direction.

When the susceptor angle is made variable, it is desirable that the shower plate angle be also made variable. Here, a mechanism to make the shower plate angle variable can also be implemented using micro-heads, etc., in the same manner as the corresponding mechanism for the susceptor.

In the present disclosure where conditions and/or structures are not specified, the skilled artisan in the art can readily provide such conditions and/or structures, in view of the present disclosure, as a matter of routine experimentation.

It will be understood by those of skill in the art that numerous and various modifications can be made without departing from the spirit of the present invention. Therefore, it should be clearly understood that the forms of the present invention are illustrative only and are not intended to limit the scope of the present invention.

What is claimed is:

1. A wafer-positioning mechanism comprising:
a susceptor having an upper surface for supporting a wafer thereon, said upper surface being slanted with respect to a horizontal plane at an angle such that the wafer on the upper surface slides with an aid, said aid being a gas flowing out of the upper surface against the reverse side of the wafer facing the upper surface, said upper surface having a protrusion for stopping the wafer from sliding beyond the protrusion in the sliding direction by contacting an edge of the wafer where the wafer is positioned on the upper surface for wafer processing.

2. The wafer-positioning mechanism according to claim 1, wherein the angle is 1° to 15° with respect to the horizontal plane.

3. The wafer-positioning mechanism according to claim 1, wherein the protrusion is comprised of multiple guide pins disposed only in a lower half of the slanted upper surface.

4. The wafer-positioning mechanism according to claim 1, wherein the protrusion is comprised of a step or steps disposed only in a lower half of the slanted upper surface.

5. The wafer-positioning mechanism according to claim 1, wherein the protrusion is integrally formed with the upper surface and made of the same material as that constitutes the upper surface.

6. The wafer-positioning mechanism according to claim 1, wherein the upper surface of the susceptor has multiple holes for discharging gas therefrom against the reverse side of the wafer placed on the upper surface.

7. The wafer-positioning mechanism according to claim 6, wherein the multiple holes are holes for wafer lift pins.

8. The wafer-positioning mechanism according to claim 1, wherein the susceptor is supported by a susceptor support, wherein an axis of the susceptor support is vertical.

9. The wafer-positioning mechanism according to claim 1, wherein the susceptor is supported by a susceptor support, wherein an axis of the susceptor support is perpendicular to the upper surface of the susceptor.

10. The wafer-positioning mechanism according to claim 1, further comprising a shower plate disposed facing the susceptor

11. The wafer positioning mechanism according to claim 10, wherein the shower plate is disposed parallel to the susceptor.

12. A method for positioning a wafer on an upper surface of a susceptor, comprising:
placing a wafer on lift pins extending from an upper surface of a susceptor;
retracting the lift pins to place the wafer on the upper surface; and
positively sliding the wafer upon the upper surface until the wafer is positioned for wafer processing.

13. The method according to claim 11, wherein the upper surface is slanted with respect to a horizontal plane at an angle such that the wafer on the upper surface slides with an aid, said aid being a gas flowing out of the upper surface against the reverse side of the wafer facing the upper surface, said upper surface having a protrusion for stopping the wafer from sliding beyond the protrusion in the sliding direction by contacting an edge of the wafer where the wafer is positioned on the upper surface for wafer processing, wherein the step of positively sliding the wafer comprises:
discharging gas from the upper surface of the susceptor against the reverse side of the wafer, thereby sliding the wafer toward the protrusion; and
stopping the wafer at the protrusion by contacting an edge of the wafer.

14. The method according to claim 13, wherein the angle is 1° to 15° with respect to the horizontal plane.

15. The method according to claim 13, wherein the gas is discharged from multiple holes formed on the upper surface where the wafer is placed.

16. The method according to claim 15, wherein the multiple holes are holes for wafer lift pins

17. The method according to claim 13, wherein placing the wafer comprises placing the wafer between a shower plate for dispensing process gas and the susceptor

18. The method according to claim 17, wherein the shower plate and the susceptor upper surface are parallel to one another angled by 1° to 15° with respect to a horizontal plane.

19. An apparatus for processing a wafer, comprising:
a reaction chamber;
a susceptor disposed in the reaction chamber, the susceptor having an upper surface for supporting a wafer thereon, said upper surface being slanted with respect to a horizontal plane at an angle, said upper surface having a protrusion for stopping the wafer from sliding beyond the protrusion in the sliding direction by contacting an edge of the wafer where the wafer is positioned on the upper surface for wafer processing; and
a shower plate disposed in the reaction chamber, said shower plate being disposed facing and parallel to the susceptor.

20. The apparatus according to claim 19, further comprising a radio-frequency (RF) power source for applying RF power between the shower plate and the susceptor to generate a plasma therebetween.

21. The apparatus according to claim 19, wherein the angle of the susceptor is 5° to 15° with respect to the horizontal plane.

22. The apparatus according to claim 19, wherein the susceptor is supported by a susceptor support, wherein an axis of the susceptor support is vertical.

23. The apparatus according to claim 19, wherein the susceptor is supported by a susceptor support, wherein an axis of the susceptor support is perpendicular to the upper surface of the susceptor.

24. The apparatus according to claim 19, wherein the angle of the susceptor is adjustable by mechanically adjusting an angle of upper surface of the susceptor relative to the axis of the susceptor support.

25. The apparatus according to claim 19, further comprising gas holes in the upper surface of the susceptor communicating with a gas source, the gas holes configured to reduce friction and aid wafer sliding across the upper surface toward the protrusion.
